(19) United States
(12) Patent Application Publication
(10) Pub. No.: US 2020/0086539 A1
(43) Pub. Date: Mar. 19, 2020

(54) CASE, PREPARATION METHOD THEREOF AND ELECTRONIC PRODUCT

(71) Applicant: BYD COMPANY LIMITED, Shenzhen (CN)

(72) Inventors: Changtao ZHAO, Shenzhen (CN); Jihou WANG, Shenzhen (CN); Chencen LIU, Shenzhen (CN)

(21) Appl. No.: 16/470,803

(22) PCT Filed: Dec. 1, 2017
(86) PCT No.: PCT/CN2017/114263

§ 371 Date: Jun. 18, 2019

(30) Foreign Application Priority Data
Dec. 21, 2016 (CN) 201611190975.0

(51) Int. Cl. B29C 45/14; H05K 5/03; C08J 5/04; C09D 11/101; C09J 5/02; C09J 175/12; C09J 163/00; C09J 179/08; C09J 133/04

(52) U.S. Cl. CPC B29C 45/14311; H05K 5/03; B29C 45/14434; C08J 5/043; C09D 11/101; H05K 5/04; C09J 175/12; C09J 163/00; C09J 179/08; C09J 133/04; C09J 5/02

(57) ABSTRACT

The present disclosure provides a case, a preparation method thereof and an electronic product. The case includes a glass cover plate, a plastic frame body and a metal substrate frame, where the glass cover plate, the plastic frame body and the metal substrate frame are sequentially bonded without steps. The method includes: (1) coating an edge of a glass cover plate with a first activator, and then drying; and (2) bonding the glass cover plate obtained in step (1) with a metal substrate frame by injection molding.

### FIELD

The present invention relates to the technical field of electronic products and, in particular, to a case, a preparation method thereof, and an electronic product.

### BACKGROUND

In the prior art, the bonding manner of a glass front screen and a metal substrate frame is usually directly assembled by glue. For example, most mobile phone screens are assembled by placing a plastic gasket (soft) between the glass and the metal substrate frame and coating the glass and metal substrate frame with the glue. Therefore, the bonding manner of the glass and the metal substrate frame determines a bonding force between the metal substrate and the glass. The case prepared by the method has the following major disadvantages: (1) the glass and the metal substrate have a small bonding force therebetween, are not tightly bonded with a gap, are not waterproof, and are easy to fall off; (2) substantially all the assemblies do not achieve bonding with no steps, resulting in protruding glass, which not only increases the thickness of the case, but also increases the risk of breaking the screen; and (3) there are many preparation steps, which increases the production cost and also increases the defect rate.

### SUMMARY

To overcome the above-mentioned defects in the prior art, the present invention provides a case, a preparation method thereof and an electronic product. In the case, the glass cover plate and the metal substrate frame are bonded with no seams or steps, so the case has a high bonding force between the glass and the metal substrate, a low risk of breaking the screen and a high waterproof ability.

To achieve the above objectives, in a first aspect of the present invention, the present invention provides a case, including a glass cover plate, a plastic frame body and a metal substrate frame, where the glass cover plate, the plastic frame body and the metal substrate frame are sequentially bonded without steps.

In a second aspect of the present invention, the present invention provides a preparation method of a case, including:

(1) coating an edge of a glass cover plate with a first activator, and then drying; and

(2) bonding the glass cover plate obtained in step (1) with a metal substrate frame by injection molding.

In a third aspect of the present invention, the present invention provides a case, where the case is prepared by the method described above.

In a fourth aspect of the present invention, the present invention provides an electronic product, where the electronic product includes the case of the present invention.

In the case of the present invention, the bonding force between the glass cover plate and the metal substrate can be as high as 700 N or more (speed 10 mm/min). The glass cover plate and the metal substrate frame are bonded without seams or steps by means of a plastic frame body (by injection molding, especially room-temperature injection molding, the use of plastic as an intermediate to bond the metal substrate and the glass cover plate greatly enhances the bonding force therebetween, and the glass cover plate, the plastic frame body and the metal substrate frame are in the same plane, and they are at the same height and are sequentially bonded without steps), so the case has a good bonding force, a low risk of breaking the screen and a high waterproof ability, is thin and attractive, and can be used as a cover plate assembly case having high practicality. The preparation method reduces the screen attaching process, reduces the production cost, and enhances the product yield.

In the method of the present invention, by coating the edge of the glass cover plate with the first activator, a first activating component of the first activator is cross-linked with the plastic for injection molding, so that the bonding force between the plastic frame body and the glass cover plate, and between the plastic frame body and the metal substrate frame can be significantly increased, and the risk of breaking the screen is reduced.

The additional aspects and advantages of the present invention will be provided in the following description, and some of the additional aspects and advantages will become clear in the following description or be understood through practice of the present invention.

### DETAILED DESCRIPTION

The embodiments of the present invention are described below in details, which are used for explaining rather than limiting the present invention.

In the description of the present invention, it should be understood that, orientations or position relationships indicated by terms such as “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, “axial”, “radial”, and “circumferential” are orientations or position relationship shown based on the accompanying drawings, and are merely used for describing the present invention and simplifying the description, rather than indicating or implying that the apparatus or element should have a particular orientation or be constructed and operated in a particular orientation, and therefore, should not be construed as a limitation on the present invention.

In addition, terms “first” and “second” are used only for description purposes, and shall not be understood as indicating or suggesting relative importance or implicitly indicating a quantity of indicated technical features. Therefore, features defined by “first” and “second” may explicitly or implicitly include at least one feature. In the description of the present invention, unless otherwise specifically limited, “multiple” means at least two, for example, two or three.

In the present invention, it should be noted that unless otherwise clearly specified and limited, the terms “mounted”, “connected”, “connection”, and “fixed” should be understood in a broad sense. For example, a connection may be a fixed connection, a detachable connection, or an integral connection; may be a mechanical connection or an electrical connection; may be a direct connection or an indirect connection by means of an intermediate medium; or may be internal communication between two elements or interaction relationship between two elements, unless otherwise clearly limited. A person of ordinary skill in the art may understand specific meanings of the terms in the present invention according to specific situations.

In the present invention, unless otherwise clearly specified and limited, that a first feature is “above” or “below” a second feature may be that the first and the second features are in contact with each other directly, or the first and the second features are in contact with each other indirectly by using an intermediate medium. Moreover, that the first feature is “above”, “over”, and “on” the second feature may be that the first feature is right above the second feature or at an inclined top of the second feature, or may merely indicate that the horizontal height of the first feature is higher than that of the second feature. That the first feature is “below”, “under”, and “beneath” the second feature may be that the first feature is right below the second feature or at an inclined bottom of the second feature, or may merely indicate that the horizontal height of the first feature is lower than that of the second feature.

Endpoints of all ranges and all values disclosed herein are not limited to the precise ranges or values, and these ranges or values should be understood as including values close to these ranges or values. For value ranges, endpoint values of the ranges, the endpoint values of the ranges and separate point values, and the separate point values can be combined with each other to obtain one or more new value ranges. These value ranges should be construed as being specifically disclosed in this specification.

In a first aspect of the present invention, the present invention provides a case. According to embodiments of the present invention, the case includes a glass cover plate, a plastic frame body and a metal substrate frame, where the glass cover plate, the plastic frame body and the metal substrate frame are sequentially bonded without steps.

In the case of the present invention, those skilled in the art should understand that the glass cover plate and the metal substrate frame are bonded by the plastic frame body without seams or steps. Specifically, the plastic frame body is a solidified and hard plastic frame body, the glass cover plate, the plastic frame body and the metal substrate are in the same plane, and they are at the same height and are sequentially bonded without steps.

In the case of the present invention, to significantly enhance the bonding force between the glass cover plate and the metal substrate and to significantly reduce the risk of breaking the screen, the material of the plastic frame body is at least one of polyamide (PA), glass fiber (GF), polycarbonate (PC) and polyphenylene sulfide (PPS). According to some embodiments of the application, the material of the plastic frame body is a mixture of at least one of polyamide, polycarbonate and polyphenylene sulfide and glass fiber, According to some embodiments of the application, the material of the plastic frame body is a mixture of polyamide and glass fiber.

According to some embodiments of the application, the ratio of the total weight of at least one of the polyamide, the polycarbonate and the polyphenylene sulfide to the weight of the glass fiber in the plastic frame body is (0.5 to 5):1. According to some embodiments of the application, the ratio of the total weight of at least one of the polyamide, the polycarbonate and the polyphenylene sulfide to the weight of the glass fiber in the plastic frame body is (1 to 3):1. It should be understood by those skilled in the art that when the plastic frame body contains one of polyamide, polycarbonate and polyphenylene sulfide, the total weight of at least one of the polyamide, the polycarbonate and the polyphenylene sulfide is the weight of the one, and when the plastic frame body contains two or more of polyamide, polycarbonate and polyphenylene sulfide, the total weight of at least one of the polyamide, the polycarbonate and the polyphenylene sulfide is the sum of the two or more. In the present invention, the polyamide, the glass fiber, the polycarbonate and the polyphenylene sulfide are various commonly used polyamides, glass fibers, polycarbonates and polyphenylene sulfides, all of which are commercially available.

In the case of the present disclosure, the material of the metal substrate frame is not particularly limited, and may be various metal substrates commonly used in the art. According to some embodiments of the application, the material of the metal substrate frame may be a stainless steel substrate or an aluminum alloy substrate.

In the case of the present disclosure, to further enhance the bonding force between the glass cover plate and the metal substrate and to significantly reduce the risk of breaking the screen, according to some embodiments of the application, an anodic oxide film layer is formed on a surface of the metal substrate frame, and a micropore is formed in an outer surface layer of the anodic oxide film layer. The metal substrate frame may be prepared by a method including the following steps: sequentially performing machine shaping, polishing, chemical polishing, sandblasting, anodic oxidation treatment, micropore treatment and film attaching treatment on stainless steel or aluminum alloy. The specific steps are detailed below.

In the case of the present disclosure, the sizes of the glass cover plate, the plastic frame body and the metal substrate frame are not particularly limited, and can be correspondingly designed according to actual needs, and the specific size design is well known to those skilled in the art and will not be described herein.

In a second aspect of the present disclosure, the present disclosure provides a preparation method of a case. According to an embodiment of the present disclosure, the method includes:

(1) coating an edge of a glass cover plate with a first activator, and then drying; and

(2) bonding the glass cover plate obtained in step (1) with a metal substrate frame by injection molding.

In the method of the present disclosure, according to some embodiments of the application, the method further includes: in step (1), before coating with the first activator, coating at least the edge of the glass cover plate with ink in advance, and then curing. It is possible to determine which parts of the glass cover plate are coated with the ink according to the application of the case, for example, if the case is used as a front screen cover plate case, the edge of the glass cover plate is only coated with the ink, and the ink mainly shields an ITO circuit; and if the case is used as a rear screen cover plate case, the inner surface of the glass cover plate (including the edge of the inner surface) is coated with the ink, and the ink mainly displays the color of the rear screen cover plate case.

In the method of the present disclosure, in step (1), to enhance the bonding force between the glass cover plate and the metal substrate and reduce the risk of breaking the screen, according to some embodiments of the application, the glass cover plate is a glass cover plate whose edge is subjected to roughening treatment to increase its surface roughness. The roughening treatment is well known to those skilled in the art and will not be described herein.

In the method of the present disclosure, in step (1), the ink is not particularly limited, and may be various inks commonly used in the art. According to some embodiments of the application, the ink is a UV ink or a thermosetting ink.

In step (1), the manner of coating is not particularly limited, and may be any manner that can achieve coating. For convenience of production, according to some embodiments of the application, the manner of coating with the ink is screen printing, and the thickness of the ink for screen printing is 5 μm to 15 μm. The specific method of screen printing is well known to those skilled in the art and will not be described herein.

In the method of the present disclosure, in step (1), to significantly enhance the bonding force between the glass cover plate and the metal substrate and to significantly reduce the risk of breaking screen, according to some embodiments of the application, the first activator includes a first activating component, a first diluent and a first curing agent. Based on the weight of the first activator, the content of the first activating component is 80% to 94% by weight, according to some embodiments of the application, based on the weight of the first activator, the content of the first activating component is 85% to 91% by weight, the content of the first diluent is 5% to 19% by weight, according to some embodiments of the application ,the content of the first diluent is 6% to 10% by weight, and the content of the first curing agent is 1% to 10% by weight, according to some embodiments of the application , content of the first curing agent is 3% to 5% by weight.

According to some embodiments of the present disclosure, the first activating component is at least one of polyurethane, epoxy resin, polyimide and polyacrylate.

According to some embodiments of the present disclosure, the first diluent is at least one of acetone, ethyl acetate and ethyl acetate.

According to some embodiments of the present disclosure, the first curing agent is at least one of ethylenediamine, ethylene glycol, glycerol and diethylenetriamine.

To further enhance the bonding force between the glass cover plate and the metal substrate and further reduce the risk of breaking the screen, according to some embodiments of the present disclosure, in step (1), the thickness of the coated first activator is 5 μm to 15 μm. The manner of coating may be screen printing. The method of screen printing may include: reciprocally printing two layers using a 300 to 380 mesh screen. The specific operation method is well known to those skilled in the art and will not be described herein.

In the method of the present disclosure, in step (1), the conditions for curing after coating with the ink are not particularly limited, may be selected according to the type of the ink, and are various conditions commonly used in the art. When the ink is a UV ink, the manner of curing is exposure. According to some embodiments of the present disclosure, the exposure conditions include: the power is 500 kW to 1200 kW, and the time is 1 min to 5 min. When the ink is a thermosetting ink, the manner of curing is drying. According to some embodiments of the present disclosure, the conditions for drying include: the temperature is 80° C. to 90° C., and the time is 50 min to 100 min.

In the method of the present disclosure, in step (1), the conditions for drying after coating with the first activator are not particularly limited, and may be various conditions commonly used in the art. According to some embodiments of the present disclosure, the conditions for drying include: the temperature is 75° C. to 90° C., and the time is 40 to 120 min. To achieve the desired results, after drying, injection molding should be performed as soon as possible. If the storage period is longer, the required injection molding temperature is higher.

In the method of the present disclosure, in step (2), the material of the metal substrate frame is not particularly limited, and may be various metal substrates commonly used in the art. According to some embodiments of the present disclosure, the material of the metal substrate frame may be a stainless-steel substrate or an aluminum alloy substrate.

The metal substrate frame in the prior art is generally prepared by a method including the following steps: sequentially performing machine shaping, polishing, chemical polishing, sandblasting, anodic oxidation treatment and film attaching treatment on stainless steel or aluminum alloy. To further enhance the bonding force between the glass cover plate and the metal substrate and further reduce the risk of breaking the screen, According to some embodiments of the present disclosure, the metal substrate frame is prepared by a method including the following steps: sequentially performing machine shaping, polishing, chemical polishing, sandblasting, anodic oxidation treatment, micropore treatment and film attaching treatment on stainless steel or aluminum alloy (the film is attached to the metal frame to prevent the anodic oxide film from being scratched). A microporous pretreatment is added after the anodic oxidation treatment, so that micron-sized etching pores are formed in the outer surface layer of the anodic oxide film layer. Through such etching reformed pores, in the subsequent molding process, the plastic material is more likely to directly enter the surface pores of the substrate during the injection molding process, thereby forming good bonding with the substrate after forming the plastic frame body, and further enhancing the bonding force between the glass cover plate and the metal substrate.

According to some embodiments of the present disclosure, the manner of micropore treatment is performed by soaking the substrate obtained by the anodic oxidation treatment in an etching solution, and forming etching pores having a pore diameter of 200 nm to 2000 nm in the outer surface layer of the anodic oxide film layer. The etching solution may be a solution for etching the anodic oxide film layer, for example, generally adjusting the concentration of a solution capable of dissolving aluminum oxide, and may be an acid/alkali etching solution, for example, may be selected from a solution having a pH of 10 to 13. According to some embodiments of the present disclosure, the etching solution may be a single alkaline solution or a composite buffer solution having a pH of 10 to 13. The single alkaline solution having a pH of 10 to 13 may be an aqueous solution of Na₂CO₃, NaHCO₃, NaOH, K₂CO₃, KHCO₃, KOH or the like, according to some embodiments of the present disclosure the single alkaline solution having a pH of 10 to 13 may be an aqueous solution of Na₂CO₃, NaHCO₃ or Na₂CO₃ and NaHCO₃, which can enable the etching pores to be uniformly distributed in the surface of the substrate with uniform pore diameter and enables better bonding between the glass cover plate and the substrate. The above etching solution may have a solid content of 0.1% to 15% by weight. The composite buffer solution may be a mixed solution of a soluble hydrogen phosphate and a soluble base, for example, an aqueous solution of sodium dihydrogen phosphate and sodium hydroxide. The aqueous solution of sodium dihydrogen phosphate and sodium hydroxide may have a solid content of 0.1% to 15% by weight, or may be an aqueous solution of K₃PO₄ and K₂HPO₄. The composite buffer solution may also be an aqueous ammonia solution, an aqueous solution of hydrazine, an aqueous solution of an hydrazine derivative, an aqueous solution of a water-soluble amine compound, an aqueous solution of NH₃—NH₄Cl, or the like. The soaking the substrate obtained by the anodic oxidation treatment in an etching solution includes: repeatedly soaking the substrate in the etching solution, where the time of each soaking may be 1 min to 60 min, and after each soaking, washing with deionized water, where the number of times of soaking may be 2 to 10. The washing may be washing in a washing tank for 1 min to 5 min, or standing in a washing tank for 1 min to 5 min.

The methods for machine shaping, polishing, chemical polishing, sandblasting, anodic oxidation treatment and film attaching treatment are not particularly limited, and may be various methods commonly used in the art, which are well known to those skilled in the art. For example, the conditions for sandblasting may include: the sandblasting pressure is 0.23 MPa to 0.25 MPa, reciprocating is carried out for 2 times to 4 times, and the running speed is 12 Hz to 22 Hz, where 205 ceramic sand may be used, and the oscillation frequency may be 33 Hz (machine fixed frequency). The conditions for anodic oxidation treatment may include: the concentration of sulfuric acid in the electrolyte is 10 to 30wt %, the concentration of aluminum ions is 10 g/L to 30 g/L; the temperature is 15° C. to 25° C., the current density is 0.6 A/dm² to 3 A/dm², the voltage is 10 V to 20 V, and the oxidation time is 30 min to 50 min.

In the method of the present disclosure, to further enhance the bonding force between the glass cover plate and the metal substrate and further reduce the risk of breaking the screen, According to some embodiments of the present disclosure, the method further includes: before the injection molding, coating the inner edge of the metal substrate frame with a second activator in advance, and then drying.

To significantly enhance the bonding force between the glass cover plate and the metal substrate and to significantly reduce the risk of breaking screen, according to some embodiments of the present disclosure, the second activator with which the inner edge of the metal substrate frame is coated with includes a second activating component, a second diluent and a second curing agent. Based on the weight of the second activator, the content of the second activating component is 80 to 94wt %, more According to some embodiments of the present disclosure 85% to 91% by weight, the content of the second diluent is 5% to 19% by weight, more According to some embodiments of the present disclosure 6% to 10% by weight, and the content of the second curing agent is 1% to 10% by weight, more According to some embodiments of the present disclosure 3% to 5% by weight.

According to some embodiments of the present disclosure, the second activating component is at least one of polyurethane, epoxy resin, polyimide and polyacrylate.

According to some embodiments of the present disclosure, the second diluent is at least one of acetone, ethyl acetate and ethyl acetate.

According to some embodiments of the present disclosure, the second curing agent is at least one of ethylenediamine, ethylene glycol, glycerol and diethylenetriamine.

To further enhance the bonding force between the glass cover plate and the metal substrate and further reduce the risk of breaking the screen, according to some embodiments of the present disclosure, the thickness of the second activator with which the edge of the metal substrate frame is coated is 5 μm to 15 μm.

The conditions for drying after coating the edge of the metal substrate frame with the second activator are not particularly limited, and may be various conditions commonly used in the art. According to some embodiments of the present disclosure, the conditions for drying include: the temperature is 75° C. to 90° C., and the time is 40 min to 120 min.

In the method of the present disclosure, According to some embodiments of the present disclosure, in step (2), the manner of injection molding is room-temperature injection molding, and more According to some embodiments of the present disclosure, the conditions for injection molding include: the injection molding width is 0.5 mm to 1 mm, the mold temperature is 15° C. to 35° C., and the injection molding material temperature is 200° C. to 300° C.

In the method of the present disclosure, to significantly enhance the bonding force between the glass cover plate and the metal substrate and significantly reduce the risk of breaking the screen, according to some embodiments of the present disclosure, the injection molding material is at least one of polyamide, glass fiber, polycarbonate and polyphenylene sulfide, more according to some embodiments of the present disclosure a mixture of at least one of polyamide, polycarbonate and polyphenylene sulfide and glass fiber, further more according to some embodiments of the present disclosure a mixture of polyamide and glass fiber.

According to some embodiments of the present disclosure, the ratio of the total weight of at least one of the polyamide, the polycarbonate and the polyphenylene sulfide to the weight of the glass fiber is (0.5 to 5):1. According to some embodiments of the present disclosure, the ratio of the total weight of at least one of the polyamide, the polycarbonate and the polyphenylene sulfide to the weight of the glass fiber is (1 to 3):1. It should be understood by those skilled in the art that when the injection molding material contains one of polyamide, polycarbonate and polyphenylene sulfide, the total weight of at least one of the polyamide, the polycarbonate and the polyphenylene sulfide is the weight of the one, and when the injection molding material contains two or more of polyamide, polycarbonate and polyphenylene sulfide, the total weight of at least one of the polyamide, the polycarbonate and the polyphenylene sulfide is the sum of the two or more.

In the method of the present disclosure, as described above, according to an embodiment of the present disclosure, the edge of the glass cover plate is subjected to roughening treatment, and at the same time, the metal substrate frame is subjected to micropore treatment to form numerous nano micropores in the surface thereof. The activator is screen printed on the glass cover plate and the metal substrate after treatment, and then the glass cover plate is placed in the metal substrate frame by room-temperature injection molding, thereby achieving the bonding of the metal substrate, the plastic and the glass cover plate without steps.

According to some embodiments of the present disclosure, the glass cover plate (especially the case as the front screen cover plate case) is OGS (a touch panel with the same name as One Glass Solution, one piece of glass serves as cover glass and a touch sensor at the same time) touch screen tempered glass, thereby reducing the thickness of the product and breaking through the barrier of the influence of the injection molding temperature on the touch screen, so that the glass cover plate and the metal substrate frame are integrally formed, which can reduce the product steps, reduce the cost, improve the performance of the product and decorate the appearance of the product, making the product lighter and more practical.

In the method of the present disclosure, the method further includes: removing excess burrs after injection molding.

In a third aspect of the present disclosure, the present disclosure provides a case prepared by the foregoing method of the present disclosure.

In a fourth aspect of the present disclosure, the present disclosure provides an electronic product, where the electronic product includes the foregoing case of the present disclosure.

The electronic product is not particularly limited as long as the electronic product has a glass cover plate and a metal substrate frame. According to some embodiments of the present disclosure, the electronic product is a mobile phone, a tablet computer, a game machine, a watch, a notebook computer, a desktop computer, a television or a meter display.

According to some embodiments of the present disclosure, the case is a front screen cover plate case, a rear screen cover plate case or a waterproof watch case of the electronic product. More According to some embodiments of the present disclosure, the case can be applied to a 2.5 D front screen to improve the decorative effect of the product.

The present disclosure will now be described with reference to specific embodiments. It is to be noted that these embodiments are merely illustrative and are not intended to limit the present disclosure in any way.

The present disclosure will be described in detail below by way of embodiments. In the following embodiments, the reagent materials used are commercially available unless otherwise specified, and the methods used are all conventional methods in the art.

The polyurethane was purchased from DuPont under the designation PA66 HTN501.

The epoxy resin was purchased from DuPont under the designation PKHH.

The polyimide was purchased from DuPont under the designation 200H.

The polyacrylate was purchased from Guangzhou Ketai Chemical Co., Ltd. under the designation 7732-18-5.

The polyamide was purchased from DuPont under the designation 73G20L.

The glass fiber was purchased from DuPont under the designation FR530 NC010.

The polycarbonate was purchased from DuPont under the designation CG943.

The polyphenylene sulfide was purchased from DuPont under the designation HTN52G35HSL.

The conditions for sandblasting include: 205 ceramic sand is used, sandblasting pressure is 0.24 MPa, reciprocating is carried out for 3 times, running speed is 18 Hz, and the oscillation frequency is 33 Hz.

### Embodiment 1

(1) The edge of OGS touch screen tempered glass was subjected to roughening treatment, a UV ink was screen printed on the edge of the glass by using a 70T screen, the screen printed thickness of the UV ink being 10 μm, and then exposure was performed for 3 min under a 900 kW exposure machine. An activator was screen printed on the UV ink by using a 380 mesh screen, the screen printed thickness of the activator being 10 μm, and then the glass was dried in a tunnel dryer at 90° C. for 90 min. The activator was a polyurethane system, including polyurethane, acetone and ethylenediamine. Based on the weight of the activator, the contents of the polyurethane, the acetone and the ethylenediamine were 88wt %, 8wt % and 4wt % respectively.

(2) Aluminum alloy was sequentially subjected to machine shaping, polishing, chemical polishing, sandblasting, anodic oxidation treatment, micropore treatment and film attaching treatment to obtain an aluminum alloy substrate frame, then the inner edge of the aluminum alloy substrate frame was coated with the same activator as step (1), the coating thickness being 10 μm, and drying was performed at 80° C. for 90 min. The conditions for anodic oxidation treatment included: the concentration of sulfuric acid in the electrolyte was 20wt %, the concentration of aluminum ions was 20 g/L, the temperature was 20° C., the current density was 1.5 A/dm², the voltage was 15 V, and the oxidation time was 40 min. The conditions for micropore treatment included: the substrate was soaked in a 10wt % sodium carbonate solution having a pH of 12, taken out after 5 min, and soaked in a beaker containing water for 1 min, such cycle was performed 5 times, and after the last time of soaking in water, drying was performed.

(3) The injection molding material (polyamide and glass fiber mixed according to a weight ratio of 2:1) was placed in an oven and preheated to 250° C., and the glass cover plate obtained in step (1) and the aluminum alloy substrate frame obtained in step (2) were bonded by room-temperature injection molding. The injection molding width was 0.8 mm, the mold temperature was 30° C., and the injection molding material temperature was 250° C.

(4) The excess burrs were removed to obtain the case product A1.

### Embodiment 2

(1) The edge of OGS touch screen tempered glass was subjected to roughening treatment, a thermosetting ink was screen printed on the edge of the glass by using a 70T screen, the screen printed thickness of the thermosetting ink being 15 μm, and then drying was performed in an oven at 80° C. for 90 min. An activator was screen printed on the thermosetting ink by using a 300 mesh screen, the screen printed thickness of the activator being 15 μm, and then the glass was dried in a tunnel dryer at 80° C. for 110 min. The activator was a polyurethane system, including polyurethane, ethyl acetate and ethylene glycol. Based on the weight of the activator, the contents of the polyurethane, the ethyl acetate and the ethylene glycol were 85wt %, 10wt % and 5wt % respectively.

(2) Aluminum alloy was sequentially subjected to machine shaping, polishing, chemical polishing, sandblasting, anodic oxidation treatment, micropore treatment and film attaching treatment to obtain an aluminum alloy substrate frame, then the inner edge of the aluminum alloy substrate frame was coated with the same activator as step (1), the coating thickness being 15 μm, and drying was performed at 75° C. for 110 min. The conditions for anodic oxidation treatment included: the concentration of sulfuric acid in the electrolyte was 15wt %, the concentration of aluminum ions was 28 g/L, the temperature was 15° C., the current density was 1 A/dm², the voltage was 10 V, and the oxidation time was 50 min. The conditions for micropore treatment included: the substrate was soaked in a 15 wt % sodium bicarbonate solution having a pH of 10, taken out after 5 min, and soaked in a beaker containing water for 1 min, such cycle was performed 5 times, and after the last time of soaking in water, drying was performed.

(3) The injection molding material (polyamide and glass fiber mixed according to a weight ratio of 1:1) was placed in an oven and preheated to 300° C., and the glass cover plate obtained in step (1) and the aluminum alloy substrate frame obtained in step (2) were bonded by room-temperature injection molding. The injection molding width was 1 mm, the mold temperature was 15° C., and the injection molding material temperature was 300° C.

(4) The excess burrs were removed to obtain the case product A2.

### Embodiment 3

(1) The edge of OGS touch screen tempered glass was subjected to roughening treatment, a thermosetting ink was screen printed on the edge of the glass by using a 70T screen, the screen printed thickness of the thermosetting ink being 5 μm, and then drying was performed in an oven at 90° C. for 60 min. An activator was screen printed on the thermosetting ink by using a 300 mesh screen, the screen printed thickness of the activator being 8 μm, and then the glass was dried in a tunnel dryer at 80° C. for 50 min. The activator was a polyurethane system, including polyurethane, ethyl acetate and diethylenetriamine. Based on the weight of the activator, the contents of the polyurethane, the ethyl acetate and the diethylenetriamine were 91 wt %, 6 wt % and 3 wt % respectively.

(2) Aluminum alloy was sequentially subjected to machine shaping, polishing, chemical polishing, sandblasting, anodic oxidation treatment, micropore treatment and film attaching treatment to obtain an aluminum alloy substrate frame, then the inner edge of the aluminum alloy substrate frame was coated with the same activator as step (1), the coating thickness being 5 and drying was performed at 90° C. for 60 min. The conditions for anodic oxidation treatment included: the concentration of sulfuric acid in the electrolyte was 25wt %, the concentration of aluminum ions was 15 g/L, the temperature was 25° C., the current density was 2.5 A/dm', the voltage was 20 V, and the oxidation time was 30 min. The conditions for micropore treatment included: the substrate was soaked in a 15 wt % sodium bicarbonate solution having a pH of 10, taken out after 5 min, and soaked in a beaker containing water for 1 min, such cycle was performed 5 times, and after the last time of soaking in water, drying was performed.

(3) The injection molding material (polyamide and glass fiber mixed according to a weight ratio of 3:1) was placed in an oven and preheated to 200° C., and the glass cover plate obtained in step (1) and the aluminum alloy substrate frame obtained in step (2) were bonded by room-temperature injection molding. The injection molding width was 0.5 mm, the mold temperature was 35° C., and the injection molding material temperature was 200° C.

(4) The excess burrs were removed to obtain the case product A3.

### Embodiment 4

The case product A4 was prepared according to the method of Embodiment 1, except that the activator was a polyurethane system, including polyurethane, acetone and ethylenediamine, and based on the weight of the activator, the contents of the polyurethane, the acetone and the ethylenediamine were 80 wt %, 10 wt % and 10 wt % respectively.

### Embodiment 5

The case product A5 was prepared according to the method of Embodiment 1, except that the epoxy resin was used instead of the polyurethane in the activator.

### Embodiment 6

The case product A6 was prepared according to the method of Embodiment 1, except that the polyimide was used instead of the polyurethane in the activator.

### Embodiment 7

The case product A7 was prepared according to the method of Embodiment 1, except that the polyacrylate was used instead of the polyurethane in the activator.

### Embodiment 8

The case product A8 was prepared according to the method of Embodiment 1, except that in step (2), the inner edge of the aluminum alloy substrate frame was not coated with the activator before the injection molding.

### Embodiment 9

The case product A9 was prepared according to the method of Embodiment 1, except that the micropore treatment was not performed in the process of preparing the aluminum alloy substrate frame.

### Embodiment 10

The case product A10 was prepared according to the method of Embodiment 1, except that the injection molding material was a mixture of polycarbonate and glass fiber in a weight ratio of 2:1.

### Embodiment 11

The case product A11 was prepared according to the method of Embodiment 1, except that the injection molding material was a mixture of polyphenylene sulfide and glass fiber in a weight ratio of 2:1.

### Embodiment 12

The case product A12 was prepared according to the method of Embodiment 1, except that the injection molding material was a mixture of polyamide and glass fiber in a weight ratio of 0.5:1.

### Embodiment 13

The case product A13 was prepared according to the method of Embodiment 1, except that the injection molding material was polyphenylene sulfide.

### Embodiment 14

The case product A14 was prepared according to the method of Embodiment 1, except that the injection molding material was polyamide.

### Embodiment 15

The case product A15 was prepared according to the method of Embodiment 1, except that the injection molding material was polycarbonate.

### Embodiment 16

The case product A16 was prepared according to the method of Embodiment 1, except that the injection molding material was glass fiber.

### Comparative Embodiment 1

The method was the same as that in Embodiment 1, except that the method included steps (1) to (3).

In step (1), the edge of OGS touch screen tempered glass was subjected to roughening treatment, a UV ink was screen printed on the edge of the glass by using a 70 T screen, the screen printed thickness of the UV ink being 10 μm and then exposure was performed for 3 min under a 900 kW exposure machine.

In step (2), machine shaping, polishing, chemical polishing, sandblasting, anodic oxidation treatment and film attaching treatment were sequentially performed on aluminum alloy to obtain an aluminum alloy substrate frame.

In step (3), a plastic gasket was placed between the glass cover plate obtained in step (1) and the aluminum alloy substrate frame obtained in step (2), the glass cover plate and the aluminum alloy substrate frame are coated with glue, and the glass cover plate was placed in the aluminum alloy substrate frame, and then dried in a drying oven at 90° C. for 30 min to obtain the case D1.

### Test Embodiment

The following performance tests were performed on the cases A1 to A16 and D1 respectively.

1. Flatness test: The flatness of the surface of the glass cover plate of each case was measured by a coordinate measuring machine (purchased from HEXAGON, model: Global classic 050705). The results are shown in Table 1.

2. Mirror thrust test: A universal material mechanics testing machine (purchased from INSTRON, model 3369, propulsion speed 10 mm/min) was used to test the bonding force between the glass cover plate and the metal substrate frame of each case. The metal substrate frame was fixed, and the glass cover plate was pushed until the glass broke or the glass fell off. 30 parallel replicates were performed, and the average was taken. The results are shown in Table 1.

3. Each case was assembled into a complete machine and subjected to a drop test: no load drop test, height 1 m. After the drop test, the maximum number of times where the product did not show deformation, indentation and damage was recorded. The results are shown in Table 1.

4. Thermal shock test: Each case was placed in a thermal shock test machine (purchased from KSON, model KSKC-415TBS) to stand at −40° C. for 2 h and at 85° C. for 2 h, which was 1 cycle, and after 5 cycles, the case was stood at 25° C. for 4 h. If there was no corrosion, spots, fading, discoloration, cracking, blistering, distortion, etc. and there was no scratching of the fingernails before/after the test, the product was acceptable. The results are shown in Table 1.

5. Damp heat cycle test: Each case was placed in a thermo-hygrostat to stand at a temperature of 50° C. and a humidity of 95% for 72 h. If there was no corrosion, spots, fading, discoloration, cracking, blistering, distortion, etc. and there was no scratching of the fingernails before/after the test, the product was acceptable. The results are shown in Table 1.

6. Salt spray test: Each case was placed in a salt spray chamber, the surface of the product was sprayed continuously with a 5wt % NaCl solution having a pH value of 6.8 at a temperature of 35° C. and a humidity of 90% for 2 hours, and each product was placed in a thermo-hygrostat to stand at a temperature of 50° C. and a humidity of 95% for 22 hours, which was one cycle, and a total of 3 cycles for 72 h was performed. Then, the product was gently washed with 38° C. warm water and wiped with a dust-free cloth, and the sample was inspected after being placed at room temperature for 2 hours. If the appearance of the film layer was not abnormal and the appearance had no significant change (such as rust, discoloration and blistering, etc.), the product was acceptable. The results are shown in Table 1.

7. Chemical resistance test: Edible oil, suntan oil, lipstick, liquid foundation, a mosquito repellent, hand cream, etc. were respectively applied to each case uniformly, and after being placed in a thermo-hygrostat to stand at a temperature of 70° C. and a humidity of 90% for 24 h, the product was stood at 25° C. for 4 h, and wiped with alcohol. If there was no obvious residue, the product was acceptable. The results are shown in Table 1.

8. Waterproofness test: An IPX7 short-time water immersion test was carried out. The assembled complete machine was immersed in water for 30 minutes. The water depth of the top of the workpiece was at least 150 mm, and the lowest part was subjected to a water pressure of at least 1 m. After being taken out the water surface, the workpiece was surface-dried and allowed to stand for 30 min. If the product could work normally, it was acceptable. The results are shown in Table 1.

TABLE 1

| | | | | | | | Chemical | |
|---|---|---|---|---|---|---|---|---|
| | | Mirror | Drop | Thermal | Damp Heat | Salt Spray | Resistance | Waterproofness |
| | Flatness | Thrust | Test | Shock Test | Cycle Test | Test | Test | Test |
| A1 | ≤0.2 mm | 750 N | 300 | Acceptable | Acceptable | Acceptable | Acceptable | Acceptable |
| | | | times | | | | | |
| A2 | ≤0.2 mm | 740 N | 300 | Acceptable | Acceptable | Acceptable | Acceptable | Acceptable |
| | | | times | | | | | |
| A3 | ≤0.2 mm | 745 N | 300 | Acceptable | Acceptable | Acceptable | Acceptable | Acceptable |
| | | | times | | | | | |
| A4 | ≤0.2 mm | 680 N | 280 | Acceptable | Acceptable | Acceptable | Acceptable | Acceptable |
| | | | times | | | | | |
| A5 | ≤0.2 mm | 560 N | 250 | Acceptable | Acceptable | Acceptable | Acceptable | Acceptable |
| | | | times | | | | | |
| A6 | ≤0.2 mm | 550 N | 240 | Acceptable | Acceptable | Acceptable | Acceptable | Acceptable |
| | | | times | | | | | |
| A7 | ≤0.2 mm | 530 N | 230 | Acceptable | Acceptable | Acceptable | Acceptable | Acceptable |
| | | | times | | | | | |
| A8 | ≤0.2 mm | 380 N | 120 | Acceptable | Acceptable | Acceptable | Acceptable | Acceptable |
| | | | times | | | | | |
| A9 | ≤0.2 mm | 450 N | 200 | Acceptable | Acceptable | Acceptable | Acceptable | Acceptable |
| | | | times | | | | | |
| A10 | ≤0.2 mm | 420 N | 170 | Acceptable | Acceptable | Acceptable | Acceptable | Acceptable |
| | | | times | | | | | |
| A11 | ≤0.2 mm | 400 N | 150 | Acceptable | Acceptable | Acceptable | Acceptable | Acceptable |
| | | | times | | | | | |
| A12 | ≤0.2 mm | 520 N | 230 | Acceptable | Acceptable | Acceptable | Acceptable | Acceptable |
| | | | times | | | | | |
| A13 | ≤0.2 mm | 320 N | 80 | Acceptable | Acceptable | Acceptable | Acceptable | Acceptable |
| | | | times | | | | | |
| A14 | ≤0.2 mm | 380 N | 120 | Acceptable | Acceptable | Acceptable | Acceptable | Acceptable |
| | | | times | | | | | |
| A15 | ≤0.2 mm | 350 N | 100 | Acceptable | Acceptable | Acceptable | Acceptable | Acceptable |
| | | | times | | | | | |
| A16 | ≤0.2 mm | 260 N | 60 | Acceptable | Acceptable | Acceptable | Acceptable | Acceptable |
| | | | times | | | | | |
| D1 | ≤0.2 mm | 80 N | 30 | Acceptable | Acceptable | Acceptable | Acceptable | Unacceptable |
| | | | times | | | | | |

It can be seen from Table 1 that the method of the present disclosure can greatly enhance the bonding force between the glass cover plate and the metal substrate frame of the prepared case, thereby greatly reducing the risk of glass falling off and the risk of breaking the screen after falling, and significantly improving the product performance.

Although preferred implementations of the present disclosure have been described in detail above with reference to the accompanying drawings, the present disclosure is not limited to specific details in the foregoing implementations. Various simple variations can be made to the technical solutions of the present disclosure within the scope of the technical idea of the present disclosure, and such simple variations all fall within the protection scope of the present disclosure.

In addition, it should be noted that, the specific technical features described in the foregoing specific implementations may be combined in any suitable manner when there is no contradiction. To avoid unnecessary repetition, various possible combination manners are not additionally described in the present disclosure.

In addition, any combination may be made between various different implementations of the present disclosure, and the combination shall also be regarded as content disclosed by the present disclosure provided that it does not depart from the idea of the present disclosure.

In the descriptions of this specification, a description of a reference term such as “an embodiment”, “some embodiments”, “an example”, “a specific example”, or “some examples” means that a specific feature, structure, material, or characteristic that is described with reference to the embodiment or the example is included in at least one embodiment or example of the present disclosure. In this specification, schematic descriptions of the foregoing terms do not need to aim at a same embodiment or example. Besides, the specific features, the structures, the materials or the characteristics that are described may be combined in a proper manner in any one or more embodiments or examples. In addition, in a case that is not mutually contradictory, persons skilled in the art can combine or group different embodiments or examples that are described in this specification and features of the different embodiments or examples.

Although the embodiments of the present disclosure are shown and described above, it can be understood that, the foregoing embodiments are exemplary, and cannot be construed as a limitation to the present disclosure. Within the scope of the present disclosure, a person of ordinary skill in the art may make changes, modifications, replacement, and variations to the foregoing embodiments.

1. A case, comprising:
a glass cover plate, a plastic frame body and a metal substrate frame,
wherein the glass cover plate, the plastic frame body and the metal substrate frame are sequentially bonded without steps.

2. The case according to claim 1, wherein a material of the plastic frame body is at least one of polyamide, glass fiber, polycarbonate and polyphenylene sulfide.

3. The case according to claim 1, wherein a material of the plastic frame body is a mixture of glass fiber and at least one of polyamide, polycarbonate and polyphenylene sulfide.

4. The case according to claim 1, wherein a material of the plastic frame body is a mixture of polyamide and glass fiber.

5. The case according to claim 2, wherein a ratio of a total weight of at least one of the polyamide, the polycarbonate and the polyphenylene sulfide to a weight of the glass fiber is (0.5 to 5):1 in the plastic frame body.

6. The case according to claim 2, wherein a ratio of a total weight of at least one of the polyamide, the polycarbonate and the polyphenylene sulfide to a weight of the glass fiber is (1 to 3):1 in the plastic frame body.

7. The case according to claim 1, wherein a material of the metal substrate frame is a stainless steel substrate or an aluminum alloy substrate.

8. The case according to claim 1, wherein an anodic oxide film layer is formed on a surface of the metal substrate frame, and a micropore is formed in an outer surface layer of the anodic oxide film layer.

9. A preparation method of a case, comprising:
(1) coating an edge of a glass cover plate with a first activator, and then drying; and
(2) bonding the glass cover plate obtained in step (1) with a metal substrate frame by injection molding.

10. The method according to claim 9, further comprising: before the injection molding, coating an inner edge of the metal substrate frame with a second activator in advance, and then drying.

11. The method according to claim 9, wherein in step (1), before coating with the first activator, coating at least the edge of the glass cover plate with ink in advance, and then curing,
wherein the ink is a UV ink or a thermosetting ink, the ink is screen printing, and the thickness of the ink for screen printing is 5 μm to 15 μm.

12-13. (canceled)

14. The method according to claim 9, wherein in step (1), the first activator comprises a first activating component, a first diluent and a first curing agent, and based on the weight of the first activator, the content of the first activating component is 80% to 94% by weight, the content of the first diluent is 5% to 19% by weight, and the content of the first curing agent is 1% to 10% by weight.

15. The method according to claim 9, wherein based on the weight of the first activator, the content of the first activating component is 85% to 91% by weight, the content of the first diluent is 6% to 10% by weight, and the content of the first curing agent is 3% to 5% by weight
wherein the first activating component is at least one of polyurethane, epoxy resin, polyimide and polyacrylate,
wherein the first diluent is at least one of acetone, ethyl acetate and ethyl acetate, and
wherein the first curing agent is at least one of ethylenediamine, ethylene glycol, glycerol and diethylenetriamine.

16-18. (canceled)

19. The method according to claim 10, wherein in step (1), the thickness of the coated first activator is 5 μm to 15 μm, and wherein the thickness of the second activator with which the inner edge of the metal substrate frame is coated is 5 μm to 15 μm.

20. The method according to claim 9, wherein the second activator with which the inner edge of the metal substrate frame is coated comprises a second activating component, a second diluent and a second curing agent, and based on the weight of the second activator, the content of the second activating component is 80% to 94% by weight, the content of the second diluent is 5% to 19% by weight, and the content of the second curing agent is 1% to 10% by weight
wherein the second activating component is at least one of polyurethane, epoxy resin, polyimide and polyacrylate, the second diluent is at least one of acetone, ethyl acetate and ethyl acetate, the second curing agent is at least one of ethylenediamine, ethylene glycol, glycerol and diethylenetriamine.

21. The method according to claim 20, wherein based on the weight of the second activator, the content of the second activating component is 85% to 91% by weight, the content of the second diluent is 6% to 10% by weight, and the content of the second curing agent is 3% to 5% by weight.

22-25. (canceled)

26. The method according to claim 9, wherein in step (2), a material of the metal substrate frame is a stainless steel substrate or an aluminum alloy substrate,
wherein the metal substrate frame is prepared by a method comprising the following steps: sequentially performing machine shaping, polishing, chemical polishing, sandblasting, anodic oxidation treatment, micropore treatment and film attaching treatment on stainless steel or aluminum alloy.

27. (canceled)

28. The method according to claim 9, wherein in step (2), the conditions for injection molding comprise: the injection molding width is 0.5 to 1 mm, the mold temperature is 15° C. to 35° C., and the injection molding material temperature is 200° C. to 300° C.

29-34. (canceled)

35. An electronic product, wherein the electronic product comprises a case according to claim 1.

36. The electronic product according to claim 35, wherein the electronic product is a mobile phone, a tablet computer, a game machine, a watch, a notebook computer, a desktop computer, a television or a meter display,
wherein the case is a front screen cover plate case, a rear screen cover plate case or a waterproof watch case of the electronic product.

37. (canceled)
